(19) United States
(12) Patent Application Publication
(10) Pub. No.: US 2025/0293044 A1
(43) Pub. Date: Sep. 18, 2025

(54) SEMICONDUCTOR DEVICE AND MANUFACTURING METHOD THEREOF

(71) Applicant: Hon Young Semiconductor Corporation, Hsinchu City (TW)

(72) Inventors: Anbalagan RAMAKRISHNAN, Hsinchu City (TW); Jui-Ming LAI, Hsinchu City (TW); Chun-Yuan CHOU, Hsinchu City (TW)

(21) Appl. No.: 18/670,696

(22) Filed: May 21, 2024

(30) Foreign Application Priority Data
Mar. 15, 2024 (TW) 113109804

(51) Int. Cl. H01L 21/321; H01L 27/088; H01L 29/40; H01L 29/417; H01L 29/78

(52) U.S. Cl. CPC H01L 21/321; H10D 64/01; H10D 64/252; H10D 84/83; H10D 30/66

(57) ABSTRACT

A manufacturing method of a semiconductor device includes forming a metal layer over a substrate. The metal layer has a void therein. The manufacturing method further includes forming a coating layer fully covering the metal layer. The manufacturing method further includes performing a laser annealing process. During the laser annealing process, the metal layer flows and fills the void, while the coating layer remains substantially solid.

### CROSS-REFERENCE TO RELATED APPLICATION

This application claims priority to Taiwan Application Serial Number 113109804, filed Mar. 15, 2024, which is herein incorporated by reference in its entirety.

### BACKGROUND

### Field of Disclosure

The present disclosure relates to a semiconductor device and a manufacturing method of the semiconductor device.

### Description of Related Art

During semiconductor fabrication, metallization processes are common technologies for forming interconnect structures with various metals and alloys. The metallization processes may use fabricating methods such as sputtering, chemical vapor deposition (CVD), or electrodeposition. For example, sputtering and chemical vapor deposition may be performed sequentially to improve the coverage of the metals and the alloys on structural surfaces. However, a silicon carbide (SiC) wafer commonly used has trench structures with high aspect ratios. For example, the SiC wafer may have trench structures with aspect ratios greater than 5. Therefore, to improve yield, it is desirable to implement conformal deposition and avoid formation of voids and seams, while accomplishing thermal stress management during trench filling in the metallization processes regarding the SiC wafer.

### SUMMARY

An aspect of the disclosure is to provide a semiconductor device and a manufacturing method of the semiconductor device that may efficiently solve the aforementioned problems.

According to some embodiments of the present disclosure, a manufacturing method of a semiconductor device includes: forming a metal layer over a substrate, in which the metal layer has a void therein; forming a coating layer fully covering the metal layer; and performing a laser annealing process, in which during the laser annealing process, the metal layer flows and fills the void, while the coating layer remains substantially solid.

According to some other embodiments of the present disclosure, a manufacturing method of a semiconductor device includes: forming a contact structure over a plurality of gate structures, in which the gate structures are disposed on a semiconductor substrate and spaced apart from each other, the contact structure extends between every adjacent two of the gate structures, and the contact structure has a void therein; forming a coating layer covering the contact structure; and performing a laser annealing process, in which during the laser annealing process, the contact structure flows and fills the void, while the coating layer remains substantially solid.

According to yet some other embodiments of the present disclosure, a semiconductor device includes a plurality of gate structures, a contact structure, a coating layer, and a passivation layer. The gate structures are spacedly arranged on a semiconductor substrate. The contact structure is disposed on the gate structures and extends between every adjacent two of the gate structures. The coating layer covers the contact structure and is in contact with the contact structure. The passivation layer is disposed on the coating layer and is in contact with the coating layer.

Accordingly, in the semiconductor device and the manufacturing method of the semiconductor device of some embodiments of the present disclosure, by disposing the coating layer with a relatively low reflectivity and a relatively high boiling point on the metal layer, the laser absorption rate of the semiconductor device rises. This improves energy utilization of the laser annealing and the planarization effect of the laser annealing process can be improved.

### BRIEF DESCRIPTION OF THE DRAWINGS

The disclosure can be more fully understood by reading the following detailed description of the embodiment, with reference made to the accompanying drawings as follows:

FIG. 1 to FIG. 3 are partial cross-sectional views of intermediate stages of a manufacturing method of a semiconductor device according to some embodiments of the present disclosure;

FIG. 4 to FIG. 6 are partial cross-sectional views of intermediate stages of a manufacturing method of a semiconductor device according to some other embodiments of the present disclosure; and

FIG. 7 is a partial cross-sectional view of a semiconductor device formed by a manufacturing method according to some other embodiments of the present disclosure.

### DETAILED DESCRIPTION

Some embodiments of the present disclosure are intended to provide a semiconductor device and a manufacturing method of the semiconductor device that fills trenches and eliminates voids with a low thermal budget.

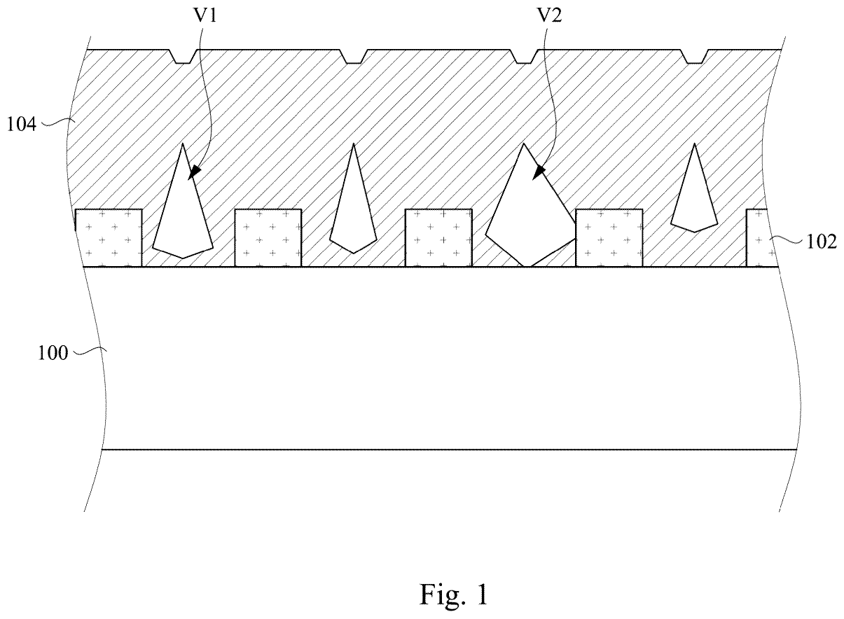

Reference is made to FIG. 1 to FIG. 3. FIG. 1 to FIG. 3 are partial cross-sectional views of intermediate stages of a manufacturing method of a semiconductor device according to some embodiments of this disclosure.

First, reference is made to FIG. 1. A metal layer 104 is formed on a substrate 100. As shown in FIG. 1, the substrate 100 may include a plurality of protruding structures 102 thereon. The protruding structures 102 may be a portion of the substrate 100 or a component connected to the substrate 100, but the present disclosure is not limited thereto. As shown in FIG. 1, the metal layer 104 is conformally deposited on the substrate 100 and the protruding structures 102 by sputtering or chemical vapor deposition. The formed metal layer 104 may have voids of various sizes between the protruding structures 102, such as a void V1 and a void V2. As shown in FIG. 1, the void V1 is completely enclosed in the metal layer 104. The void V2 has openings leading to sidewalls of the protruding structures 102 or a top surface of the substrate 100. In addition, due to the presence of the protruding structures 102, the metal layer 104 covering the protruding structures 102 has an uneven top surface. In some embodiments, the metal layer 104 includes aluminum (Al), copper (Cu), or alloys thereof such as aluminum-silicon alloy (Al—Si), aluminum-copper alloy (Al—Cu), or aluminum-silicon-copper alloy (Al—Si—Cu).

Next, a laser annealing process is performed to heat the metal layer 104 so that the metal layer 104 melts and flows, thereby filling the voids. As such, the metal layer 104 after resolidification contacts and completely covers an outer surface of the protruding structures 102.

However, since aluminum has a relatively high reflectivity (e.g., the reflectivity of aluminum at wavelengths in the visible light spectrum is between about 88% and about 92%) and a relatively high thermal conductivity, the utilization efficiency of laser energy in the laser annealing process is relatively low. In addition, aluminum has a relatively low boiling point (e.g., about 2467° C.), so aluminum may vaporize during the laser annealing process, causing the mass loss of the metal layer near its top surface. Although the boiling point of copper (e.g., about 2595° C.) is slightly higher than the boiling point of aluminum, copper has a relatively high reflectivity as well and thus is not favorable for applications of laser annealing.

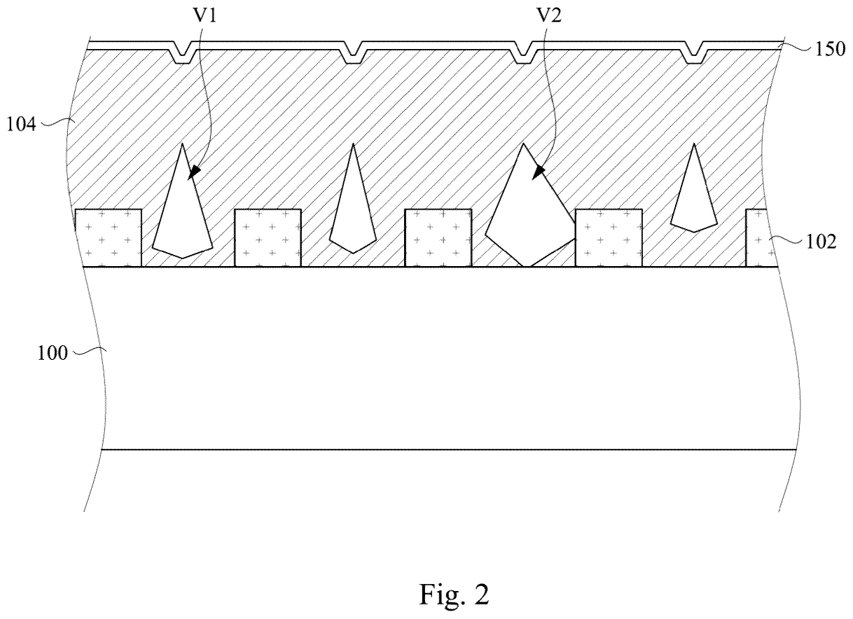

Therefore, in the manufacturing method of some embodiments of the present disclosure, before performing the laser annealing process, a coating layer (such as the coating layer 150 in FIG. 2) is firstly disposed on the metal layer as an anti-reflecting coating layer. The coating layer is made of a different material than the metal layer and has a relatively low reflectivity at the laser wavelength applied in the laser annealing process, thus improving energy utilization. For example, the reflectivity of the coating layer is at least lower than the reflectivity of the metal layer. In some embodiments, the material of the coating layer also has a relatively high boiling point, so during the laser annealing process, the coating layer covering the metal layer can help reduce the mass loss caused by the vaporization of the metal layer. Therefore, in some embodiments, the coating layer is configured to fully cover the metal layer.

In greater detail, reference is made to FIG. 2. After the metal layer 104 is formed, a coating layer 150 is formed lining and fully covering the metal layer 104. In other words, the coating layer 150 extends over the voids, such as the void V1 and the void V2, as shown in FIG. 2. As aforementioned, the metal layer 104 has an uneven top surface, so the top surface of the coating layer 150 covering the metal layer 104 may also have uneven features as the top surface of the metal layer 104 undulates.

In some embodiments, the coating layer 150 is made of a material with a relatively low reflectivity and a relatively high boiling point. For example, the coating layer 150 is made of titanium (Ti) or titanium nitride (TiN). In some embodiments, the reflectivity of the coating layer 150 at a particular wavelength of the laser is at least lower than the reflectivity of the metal layer 104 at the same wavelength of the laser. In some embodiments, the coating layer 150 has a boiling point at least higher than the boiling point of the metal layer 104 under a certain process pressure of the laser annealing process.

Next, a laser annealing process is performed through a laser having a specific wavelength under a specific process pressure. In some embodiments, the laser frequency applied is about 1000 Hz. The laser has a pulse bandwidth in a range from about 80 nanoseconds to about 120 nanoseconds. The energy density of the laser is in a range from about 0.5 Joules per square centimeter to about 3 Joules per square centimeter. The metal layer 104 is heated by the laser pulses until the metal layer 104 melts, flows, and thereby fills the voids. Meanwhile, the coating layer 150 remains substantially solid during annealing to prevent the coating layer 150 from achieving a molten state and mixing with the metal layer 104.

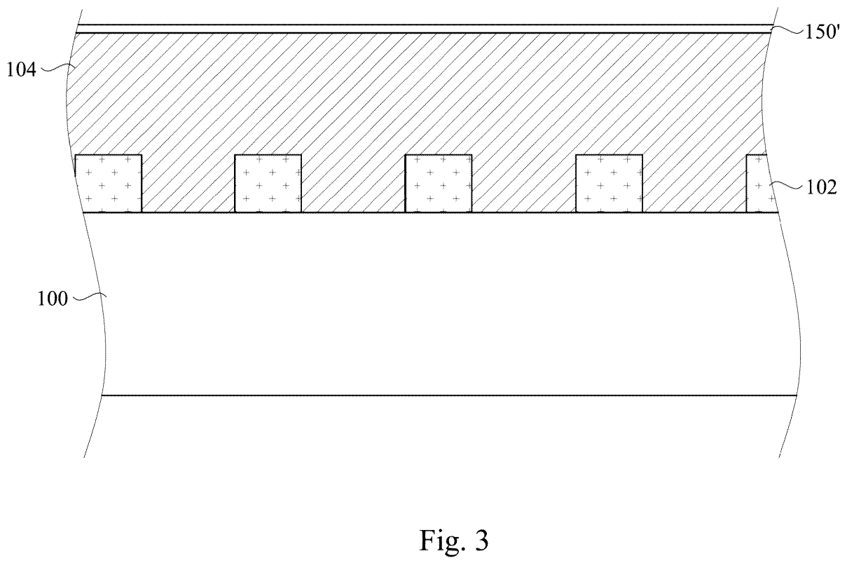

Reference is made to FIG. 3. After annealing, the void V1 and the void V2 shown in FIG. 2 are filled, and the metal layer 104 has a substantially flat top surface and completely covers the outer surface of the protruding structures 102 and structures on the top surface of the substrate 100.

It should be noted that although the coating layer 150 remains substantially solid during annealing, the fluidity of the coating layer 150 may slightly increase due to heating. Therefore, the coating layer 150 may deform due to the stress exerted by the underlying metal layer 104 during the melting and flowing of the metal layer 104. As such, the substantially flat coating layer 150′ as shown in FIG. 3 is formed. To be more specific, a roughness of the coating layer 150 before the laser annealing process may be greater than a roughness of the coating layer 150′ after the laser annealing process.

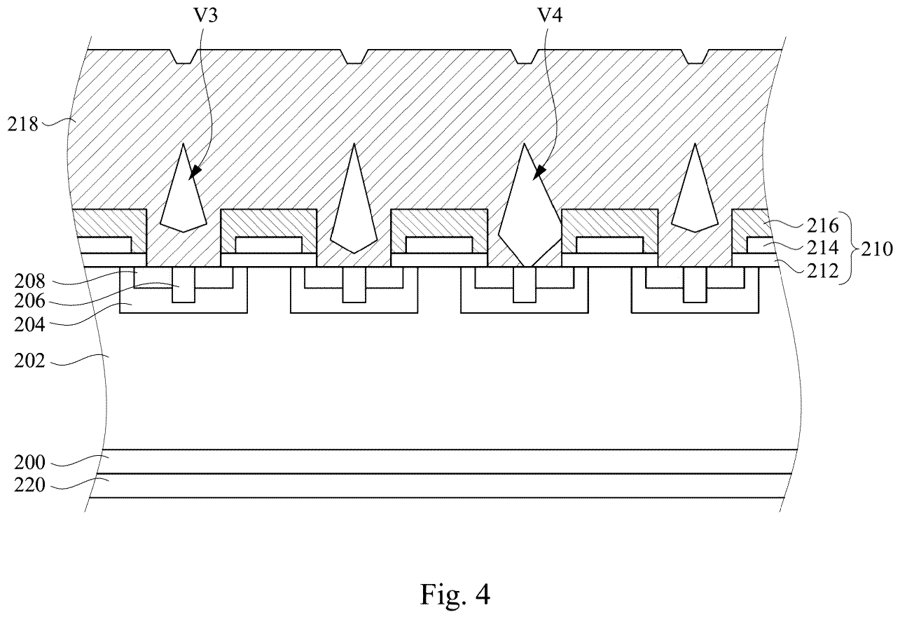

A manufacturing method of a semiconductor device according to some other embodiments of the present disclosure may be applied to form a contact structure such as a source contact of a vertical metal oxide semiconductor field effect transistor (MOSFET). For example, reference is made to FIG. 4 to FIG. 6. FIG. 4 to FIG. 6 are partial cross-sectional views of different intermediate stages of the manufacturing method applied to a vertical MOSFET.

First, reference is made to FIG. 4. In the step shown in FIG. 4, the intermediate structure of the vertical MOSFET includes an epitaxial layer 202 disposed on the semiconductor substrate 200 and a plurality of gate structures 210 disposed on the epitaxial layer 202. The epitaxial layer 202 is provided with a lightly doped region 204, a heavily doped region 206, and a source region 208. As shown in FIG. 4, each of the gate structures 210 includes a gate oxide layer 212, a gate metal 214, and an interlayer dielectric 216. The gate structures 210 are spacedly arranged. In some embodiments, another contact structure 220 is formed on a side of the semiconductor substrate 200 that is opposite to the epitaxial layer 202. In the embodiments corresponding to FIG. 4, the contact structure 220 is a drain contact.

As shown in FIG. 4, a contact structure 218 is formed over the gate structures 210. In some embodiments, the contact structure 218 extends between two adjacent gate structures 210 and over the aforementioned doped regions. There may be voids in the contact structure 218. In particular, when the contact structure 218 is conformally deposited by sputtering or chemical vapor deposition and is formed over a certain thickness, voids of various sizes may exist between two adjacent gate structures 210, such as the void V3 and the void V4 shown in FIG. 4. Similarly, the void V3 is completely enclosed in the contact structure 218. The void V4 has openings leading to sidewalls of the gate structures 210 (such as sidewalls of the interlayer dielectric 216 shown in FIG. 4) and top surfaces of the epitaxial layer 202 (such as a top surface of the heavily doped region 206 shown in FIG. 4). In the embodiments corresponding to FIG. 4, the contact structure 218 is a source contact and is electrically connected to the source region 208 of its corresponding transistor. Similarly, in some embodiments, the contact structure 218 may be made of Al, Cu, or alloys thereof such as Al—Si alloy, Al—Cu alloy, or Al—Si—Cu alloy.

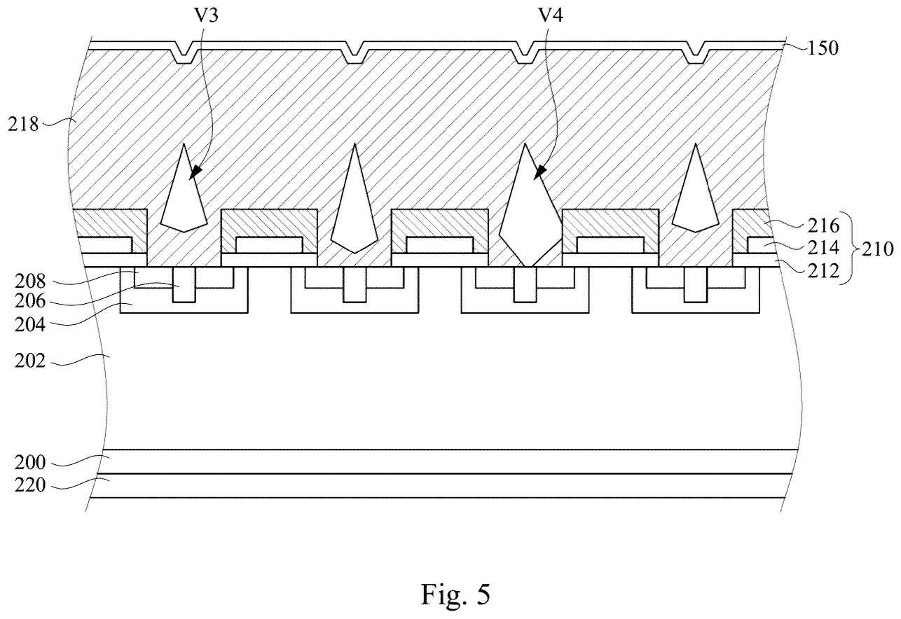

Next, reference is made to FIG. 5. A coating layer 150 is formed lining the contact structure 218 as an anti-reflective coating layer. As shown in FIG. 5, the coating layer 150 extends over the voids, such as the void V3 and the void V4, and fully covers the contact structure 218. Similarly, since the contact structure 218 has an uneven top surface, the top surface of the coating layer 150 lining the contact structure 218 may also have uneven features as the top surface of the contact structure 218 undulates.

Similarly, the coating layer 150 is made of a conductive material different from the material of the contact structure 218. In some embodiments, the material of the coating layer 150 has a relatively low reflectivity at the laser wavelength utilized in the laser annealing process and a relatively high boiling point. As such, utilization of laser energy may be improved, and the mass loss caused by the vaporization of the contact structure 218 during the annealing process may be avoided. In greater detail, the reflectivity of the coating layer 150 is lower than the reflectivity of the contact structure 218 at the applied laser wavelength. In addition, under a given process pressure, the boiling point of the coating layer 150 is higher than the boiling point of the contact structure 218.

Moreover, the material of the coating layer 150 is selected so that a melting point of the coating layer 150 is higher than a melting point of the contact structure 218. In this way, the coating layer 150 may be able to cover the contact structure 218 in a substantially solid state during the laser annealing process. The difference in the melting points of the materials of the coating layer 150 and the contact structure 218 may also prevent the two materials from melting and mixing when exposed to elevated temperatures, thereby ensuring that the source contact of the transistor has the required electrical and physical properties. For example, the coating layer 150 may be made of Ti or TiN.

Next, a laser annealing process is performed through a laser at a specific wavelength to heat the contact structure 218 so that the contact structure 218 melts, flows, and then fills the voids. As such, the contact structure 218 contacts and completely covers the outer surface of the gate structures 210. In some embodiments, the laser frequency utilized is about 1000 Hz. The laser has a pulse bandwidth in a range from about 80 nanoseconds to about 120nanoseconds. The energy density of the laser is in a range from about 0.5 Joules per square centimeter to about 3 Joules per square centimeter.

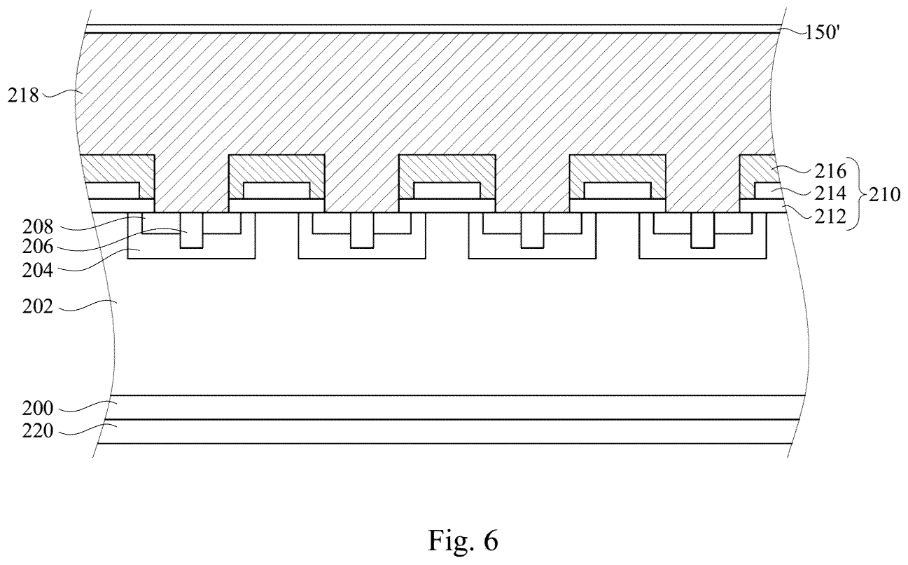

Reference is made to FIG. 6. After annealing, the void V3 and the void V4 shown in FIG. 5 are filled, and the resultant contact structure 218 has a substantially flat surface and completely covers and contacts the gate structures 210 and structures on the top surface of the epitaxial layer 202. Similarly, although the coating layer remains substantially solid during the laser annealing process, it may be slightly deformed, forming the substantially flat coating layer 150′ shown in FIG. 6. To be more specific, in some embodiments, a roughness of the coating layer 150 before the laser annealing process may be greater than a roughness of the coating layer 150′ after the laser annealing process.

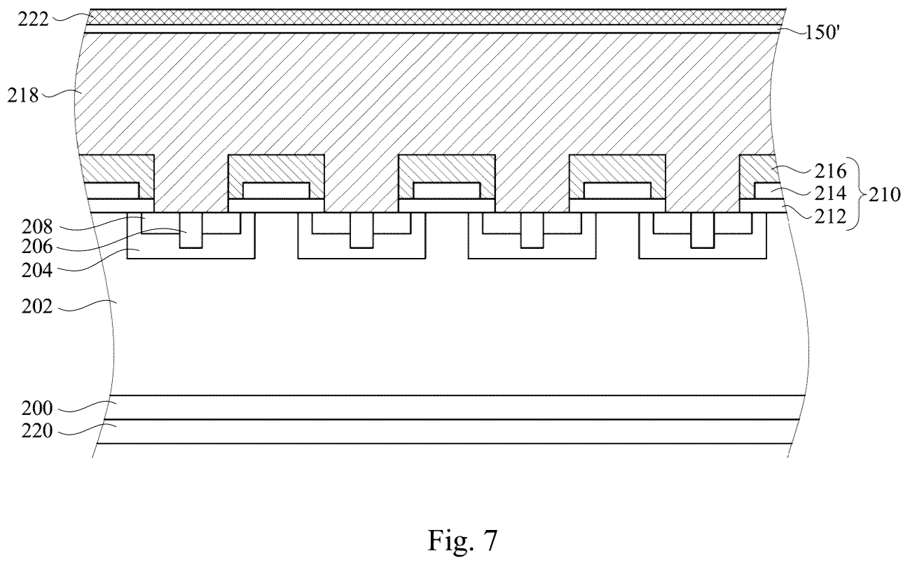

Reference is made to FIG. 7, which illustrates a partial cross-sectional view of a semiconductor device formed according to a manufacturing method of some other embodiments of the present disclosure. Since the coating layer 150′ may be made of a conductive material, such as Ti or TiN, there is no need to perform an additional process after annealing to remove the coating layer 150′. In other words, the coating layer 150′ remains on the resultant structure, and a subsequent metallization process may be directly performed on the coating layer 150′. For example, as shown in FIG. 7, a passivation layer 222 is deposited directly on the coating layer 150′. In greater detail, the passivation layer 222 is completely separated from the contact structure 218 through the coating layer 150′. In some embodiments, the passivation layer 222 may be made of silicon nitride (SiN), silicon oxide (SiO), polyimide (PI), or the like.

In still some other embodiments of the present disclosure, a MOSFET may further include a barrier metal layer. For example, the barrier metal layer may be formed lining the gate structures and the epitaxial layer. It should be noted that the thickness of the barrier metal layer is less than the thickness of the contact structure so that no distinct voids as the voids in the contact structure 218 shown in FIG. 4 are generated in the barrier metal layer. Therefore, a contact structure (e.g., a contact structure similar to the contact structure 218 in FIG. 4) may be formed over the gate structures and on the barrier metal layer. Voids may exist in the contact structure or between the contact structure and the barrier metal layer. Next, a coating layer (e.g., a coating layer similar to the coating layer 150 in FIG. 5) is formed covering the contact structure as an anti-reflective coating layer, and a laser annealing process is performed. Similarly, the coating layer extends over the voids and fully covers the contact structure. The coating layer is made of a material having a relatively low reflectivity at the laser wavelength used in the laser annealing process and a relatively high boiling point. During laser annealing, the coating layer remains substantially solid as the contact structure melts, flows, and fills the voids. Thereafter, the contact structure contacts and completely covers the barrier metal layer. The intermediate structure after the laser annealing process is similar to FIG. 6, but with a barrier metal layer between the contact structure and the gate structures. In some embodiments, the material of the barrier metal layer includes Ti or TIN. In other words, in some embodiments, the barrier metal layer and the coating layer are made of a same conductive material.

The manufacturing method of some embodiments of the present disclosure may also be applied in the fabrication of a gate metal of a trench gate metal oxide semiconductor field effect transistor to help the gate metal fill the trench and cover the gate oxide layer and to help eliminate voids in the gate metal without departing from the scope of this disclosure.

According to the foregoing recitations of the embodiments of the disclosure, it may be seen that in the semiconductor device and the manufacturing method of the semiconductor device of some embodiments of the present disclosure, by disposing the coating layer with a relatively low reflectivity and a relatively high boiling point on the metal layer, the laser absorption rate of the semiconductor device rises. This improves energy utilization of the laser annealing process and reduces the mass loss caused by the vaporization of the metal layer. To be more specific, the reflectivity of the coating layer is lower than the reflectivity of the metal layer, and under the process pressure, the boiling point of the coating layer is higher than the boiling point of the metal layer.

Therefore, the effect of planarizing the metal layer by laser annealing can be improved. In addition, the coating layer is made of materials having melting points lower than a melting point of the metal layer under the process pressure, thereby preventing the metal layer and the coating layer from achieving a molten state and mixing together during the laser annealing process. As such, when forming the metal contact structure of the transistor, the manufacturing method of some embodiments of the present disclosure can ensure that the metal contact structure has the required electrical and physical properties. Compared with common semiconductor devices and their manufacturing methods, the energy utilization rate of the laser annealing process can increase and the planarization effect of the laser annealing process can be improved.

What is claimed is:

1. A manufacturing method of a semiconductor device, comprising:
forming a metal layer over a substrate, wherein the metal layer has a void therein;
forming a coating layer fully covering the metal layer; and
performing a laser annealing process, wherein during the laser annealing process, the metal layer flows and fills the void, while the coating layer remains substantially solid.

2. The manufacturing method according to claim 1, wherein the laser annealing process is performed through a laser having a wavelength, and a reflectivity of the coating layer at the wavelength is lower than a reflectivity of the metal layer at the wavelength.

3. The manufacturing method according to claim 1, wherein under a process pressure of the laser annealing process, a boiling point of the coating layer is higher than a boiling point of the metal layer.

4. The manufacturing method according to claim 1, wherein the laser annealing process is performed through a laser having a wavelength, and a pulse bandwidth of the laser is in a range from about 80 nanoseconds to about 120 nanoseconds.

5. The manufacturing method according to claim 1, wherein the coating layer extends over the void.

6. The manufacturing method according to claim 1, wherein the coating layer is made of titanium or titanium nitride.

7. A manufacturing method of a semiconductor device, comprising:
forming a contact structure over a plurality of gate structures, wherein the gate structures are disposed on a semiconductor substrate and spaced apart from each other, the contact structure extends between every adjacent two of the gate structures, and the contact structure has a void therein;
forming a coating layer covering the contact structure; and
performing a laser annealing process, wherein during the laser annealing process, the contact structure flows and fills the void, while the coating layer remains substantially solid.

8. The manufacturing method according to claim 7, wherein the laser annealing process is performed through a laser having a wavelength, and a reflectivity of the coating layer at the wavelength is lower than a reflectivity of the contact structure at the wavelength.

9. The manufacturing method according to claim 7, wherein the void is between two of the gate structures.

10. The manufacturing method according to claim 7, wherein the contact structure is electrically connected to a source region and the source region is disposed between the semiconductor substrate and the contact structure.

11. The manufacturing method according to claim 7, wherein the coating layer extends over the void.

12. The manufacturing method according to claim 7, further comprising:
forming a barrier metal layer lining the gate structures and the semiconductor substrate,
wherein forming the contact structure comprises forming the contact structure over the gate structures and on the barrier metal layer.

13. The manufacturing method according to claim 7, wherein under a process pressure of the laser annealing process, a boiling point of the coating layer is higher than a boiling point of the contact structure.

14. The manufacturing method according to claim 7, wherein the laser annealing process is performed through a laser having a wavelength, and a pulse bandwidth of the laser is in a range from about 80 nanoseconds to about 120 nanoseconds.

15. The manufacturing method according to claim 7, wherein the coating layer is made of titanium or titanium nitride.

16. A semiconductor device, comprising:
a plurality of gate structures spacedly arranged on a semiconductor substrate;
a contact structure disposed on the gate structures and extending between every adjacent two of the gate structures;
a coating layer covering the contact structure and in contact with the contact structure; and
a passivation layer disposed on the coating layer and in contact with the coating layer.

17. The semiconductor device according to claim 16, wherein the contact structure is electrically connected to a source region and the source region is disposed between the semiconductor substrate and the contact structure.

18. The semiconductor device according to claim 16, wherein the contact structure and the coating layer are made of different conductive materials.

19. The semiconductor device according to claim 16, further comprising a barrier metal layer lining the gate structures and the semiconductor substrate, wherein the barrier metal layer and the coating layer are made of a same conductive material.

20. The semiconductor device according to claim 16, wherein the passivation layer is completely separated from the contact structure through the coating layer.
